(19) United States
(12) Patent Application Publication
(10) Pub. No.: US 2015/0076540 A1
(43) Pub. Date: Mar. 19, 2015

(54) NITRIDE SEMICONDUCTOR LIGHT EMITTING DEVICE

(71) Applicant: KABUSHIKI KAISHA TOSHIBA, Tokyo (JP)

(72) Inventors: Yoko MOTOJIMA, Yokohama (JP); Akira TANAKA, Yokohama (JP)

(73) Assignee: KABUSHIKI KAISHA TOSHIBA, Tokyo (JP)

(21) Appl. No.: 14/192,773

(22) Filed: Feb. 27, 2014

(30) Foreign Application Priority Data
Sep. 13, 2013 (JP) 2013-191196

(51) Int. Cl. H01L 33/50; H01L 33/48

(52) U.S. Cl. CPC H01L 33/505; H01L 33/483
USPC 257/98

(57) ABSTRACT

A nitride semiconductor light emitting device includes a laminate body, a first electrode, a second electrode, and a phosphor layer having a light emitting surface. The laminate body includes a first layer of a first-conductivity-type, a first part of a second layer of a second-conductivity-type, and a light emitting layer containing a nitride semiconductor between the first layer and the second layer. The first electrode is formed on a surface of the first layer. The second electrode is formed on a surface of a second part of the second layer that is formed between the laminate body and the phosphor layer. At least one of the laminate body, the second part of the second layer, and the phosphor layer has a lateral width that increase toward the light emitting surface.

### CROSS-REFERENCE TO RELATED APPLICATION

This application is based upon and claims the benefit of priority from Japanese Patent Application No. 2013-191196, filed Sep. 13, 2013, the entire contents of which are incorporated herein by reference.

### FIELD

Embodiments described herein relate generally to a nitride semiconductor light emitting device.

### BACKGROUND

Nitride semiconductor light emitting devices are widely used in illuminating devices, video displays, signals transmission, and so on.

In these applications, semiconductor light emitting devices having low operating voltages and high optical outputs are generally demanded.

In nitride semiconductor light emitting devices, it is typical to provide a p-side electrode and an n-side electrode on one surface side of a semiconductor laminate on which a step portion has been formed, and use the other surface side of the laminate as a light emitting surface.

When carriers are intensively injected into a narrow area of a light emitting layer close to the p-side electrode and the n-side electrode, Auger non-radiative recombination and carrier overflow increase. For this reason, the luminous efficiency decreases, and thus it is not possible to obtain the high optical output, and the operating voltage also becomes higher for a given output level.

Also, the directional characteristic of emitted light from the light emitting layer and the directional characteristic of wavelength converted light (that is light from the light emitting layer that has been absorbed then re-emitted by a phosphor element) are generally different. For this reason, at the outer peripheral portion of the light emitting surface, chromaticity is different from the center portion of the light emitting surface, and color irregularity will occur in the light from the light emitting device.

### DESCRIPTION OF THE DRAWINGS

FIG. 1A is a schematic cross-sectional view illustrating a nitride semiconductor light emitting device according to a first embodiment.

FIG. 1B is a schematic plan view illustrating the laminate side as seen along a line A-A of FIG. 1A.

FIGS. 2A to 2D are schematic views illustrating a process of manufacturing the nitride semiconductor light emitting device according to the first embodiment up to a wafer bonding.

FIG. 3A to 3F are schematic views illustrating the process of manufacturing the nitride semiconductor light emitting device according to the first embodiment after the wafer bonding.

FIG. 4A is a schematic cross-sectional view illustrating a nitride semiconductor light emitting device according to a first modification of the first embodiment

FIG. 4B is a schematic cross-sectional view illustrating a nitride semiconductor light emitting device according to a second modification of the first embodiment.

FIG. 5A is a schematic cross-sectional view illustrating a nitride semiconductor light emitting device according to a first comparative example.

FIG. 5B is a schematic plan view illustrating the laminate side as seen along a line A-A of FIG. 5A.

FIG. 6A is a graph illustrating light distribution characteristics for various light emitting devices obtained by simulation.

FIG. 6B is a graph illustrating a dependence of optical output on operating current for various light emitting devices obtained by simulation.

FIG. 7A is a schematic cross-sectional view illustrating a nitride semiconductor light emitting device according to a second embodiment.

FIG. 7B is a schematic plan view illustrating the laminate side as seen along a line A-A of FIG. 7A.

FIG. 8 is a schematic cross-sectional view illustrating a nitride semiconductor light emitting device according to a modification of the second embodiment.

FIG. 9 is a schematic cross-sectional view illustrating a nitride semiconductor light emitting device according to a second comparative example.

FIG. 10A is a graph illustrating light distribution characteristics for various light emitting devices obtained by simulations.

FIG. 10B is a graph illustrating a dependence of optical output on operating current for various light emitting devices obtained by simulation.

FIG. 11A is a schematic cross-sectional view illustrating a nitride semiconductor light emitting device according to a third embodiment.

FIG. 11B is a schematic plan view illustrating the laminate side as seen along a line A-A of FIG. 11A.

FIG. 12A is a graph illustrating light distribution characteristics for various light emitting devices obtained by simulation.

FIG. 12B is a graph illustrating a dependence of optical output on operating current for various light emitting devices obtained by simulation.

### DETAILED DESCRIPTION

An embodiment of a nitride semiconductor light emitting device provides a higher axial luminous intensity and less color irregularity across the light emitting device.

In general, according to one embodiment, a nitride semiconductor light emitting device includes a laminate body, a first electrode, a second electrode, and a phosphor layer having a light emitting surface. The laminate body includes a first layer having a first-conductivity-type, a first portion of a second layer having a second-conductivity-type, and a light emitting layer containing a nitride semiconductor between the first layer and the second layer. The first electrode is formed on a surface of the first layer. The second electrode is formed on a surface of a second portion of the second layer that is between the laminate body and the phosphor layer. At least one of the laminate body, the second portion of the second layer, and the phosphor layer has a lateral width that increases toward the light emitting surface.

Hereinafter, embodiments of the present disclosure will be described with reference to the accompanying drawings.

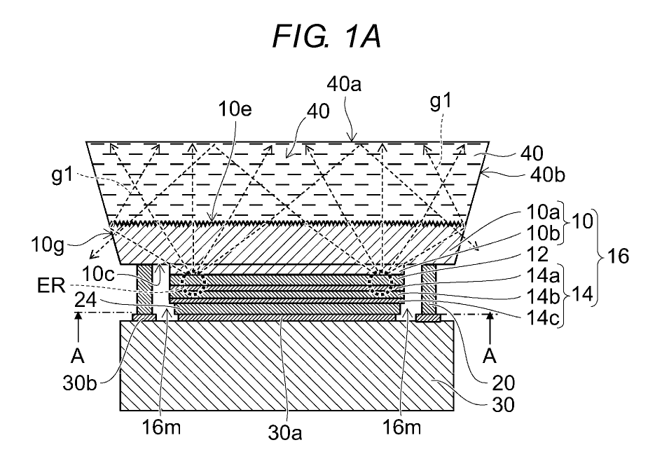

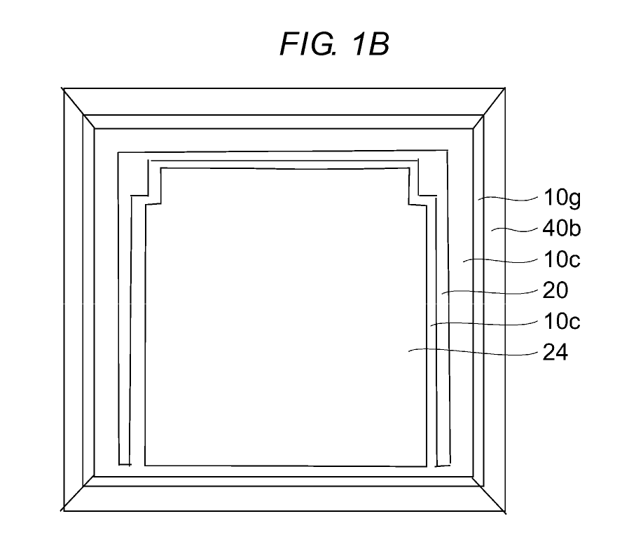

FIG. 1A is a schematic cross-sectional view illustrating a nitride semiconductor light emitting device according to a first embodiment, and FIG. 1B is a schematic plan view illustrating the laminate side as seen along a line A-A of FIG. 1A.

The nitride semiconductor light emitting device includes a laminate 16, a first electrode 24, a second electrode 20, and a phosphor layer 40.

The laminate 16 includes a first layer 14 including a first-conductive-type layer, a second layer 10 including a second-conductive-type layer, and a light emitting layer 12 provided between the first layer 14 and the second layer 10, the light emitting layer 12 includes a nitride semiconductor material. The outer peripheral portion of the laminate 16 includes a step portion 16m formed from a surface of the first layer 14 in to a portion of the second layer 10. Further, the laminate 16 has a cross section that widens between a base surface 10c of the step portion 16m and a surface 10e (which in FIG. 1A is an upper surface of the second layer 10) of the second layer 10. That is, second layer 10 has a side surface (e.g., an edge surface of portion 10a of the second layer 10) and this side surface and the base surface 10c are at an angle greater than 90 degrees (obtuse angle) to each other.

The first electrode 24 is provided on the surface of the first layer 14, and reflects a portion of emitted light from the light emitting layer 12. Further, the second electrode 20 is provided on the second layer 10 on the base surface 10c of the step portion 16m.

The phosphor layer 40 is provided on the surface 10e of the second layer 10 on the opposite side to the light emitting layer 12. Further, a surface of the phosphor layer 40 placed on the opposite side to the light emitting layer 12 is a light emitting surface 40a. In FIG. 1A, the light emitting surface 40a is an upper surface of the phosphor layer 40.

In the first embodiment, it is assumed that the phosphor layer 40 has a widening cross section, for example, such as, an inverted, truncated square pyramid. The inclination angle of the side surface of the phosphor layer 40 is substantially the same as the inclination angle of the side surface of the second layer 10 of the laminate 16; however, these side surface inclination angles may be different from each other in some embodiments.

The phosphor layer 40 absorbs light emitted from the light emitting layer 12, and then emits “wavelength converted” light having a wavelength longer than the wavelength of the emitted light. For example, in a case where the emitted light is blue light, then the phosphor layer 40 can contains a yellow phosphor, a green phosphor, a red phosphor, and the like, the phosphor layer 40 can emit white light or a colored light as mixed light.

So the second layer 10 of the laminate 16 can have a predetermined thickness, the second layer 10 placed can be thinned by etching or the like. It is typically preferable to form interfacial irregularities on the etched surface 10e because it is possible to improve light-extraction efficiency. When the phosphor layer 40 is formed on the surface 10e having irregularities (surface roughness which may sometimes referred to as “concave-convex” structures), it is possible to form irregularities on both surfaces of the phosphor layer 40, and to further improve the light-extraction efficiency.

The nitride semiconductor light emitting device may further include a support 30. The support 30 has, for example, a third electrode (first connection electrode) 30a and a fourth electrode (second connection electrode) 30b. The first electrode 24 of the surface of the laminate 16 and the third electrode 30a of the support 30 are bonded, and the second electrode 20 and the fourth electrode 30b of the support 30 are bonded. The support 30 may be formed of Si, SiC, or the like.

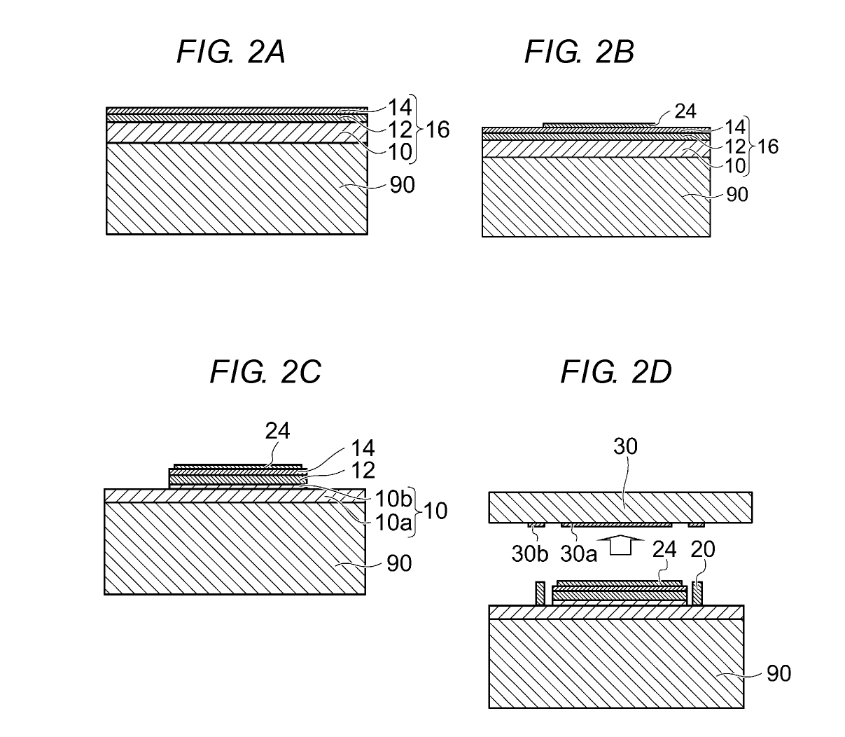

FIGS. 2A to 2D are schematic views illustrating a process of manufacturing the nitride semiconductor light emitting device according to the first embodiment, up until wafer bonding.

FIG. 2A is a schematic cross-sectional view illustrating a wafer in which the laminate 16 has been formed on a crystal growth substrate 90 that comprises sapphire, silicon, or the like. The laminate 16 can be formed on the crystal growth substrate 90 by metal-organic chemical vapor deposition (MOCVD) or other methods. The laminate 16 includes the second layer 10, the light emitting layer 12, and the first layer 14 stacked on the crystal growth substrate 90 in the stated order. In this example, the first layer 14 includes a p-type layer and the second layer 10 includes an n-type layer; however, the present disclosure is not limited to that specific arrangement.

The second layer 10 includes, for example, an n-type GaN cladding layer (where a donor concentration is 5×10¹⁸ cm⁻³ and whose thickness is 4 μm) 10a, and a superlattice layer (such as, 30 pairs of well layers with thicknesses of 1 nm and barrier layers with thicknesses of 3 nm) 10b which is formed of InGaN/InGaN. The superlattice layer 10b may be an undoped layer. Provision of the superlattice layer 10b can reduce lattice-mismatch defects in the nitride semiconductor layers.

The light emitting layer 12 may be formed of an InGaN/InGaN undoped multi-quantum well (MQW) layer (such as 3.5 pairs of well layers having thicknesses of 3 nm and barrier layers having thicknesses of 5 nm). In this case, emitted light from the light emitting layer 12 may have a wavelength in a bluish purple (violet) to blue range.

The first layer 14 includes, for example, a p-type AlGaN overflow preventing layer 14a (where an acceptor concentration is 1×10²⁰ cm⁻³ and whose thickness is 5 nm), a p-type cladding layer 14b (where an acceptor concentration is 1×10²⁰ cm⁻³ and whose thickness is 100 nm), a p-type contact layer 14c (where an acceptor concentration is 1×10²¹ cm⁻³ and whose thickness is 5 nm), and the like.

Subsequently, as shown in FIG. 2B, on the first layer 14, the first electrode 24 is formed. The first electrode 24 may be formed of gold (Au), a metal multi-layer film containing Au, a multi-layer film containing silver (Ag) at its surface, or the like. It is typically preferable that the first electrode 24 have Ag at its surface because it is possible to obtain high reflectance even with respect to a short wavelength of bluish purple to blue.

Subsequently, as shown in FIG. 2C, etching or the like is performed on the laminate 16, whereby a step portion 16m is formed from the surface of the first layer 14 up to a portion of the second layer 10. The base surface 10c of the step portion 16m may protrude to the n-type GaN cladding layer (10a) side.

Subsequently, as shown in FIG. 2D, on the base surface 10c of the step portion 16m, the second electrode 20 is formed. The second electrode 20 may be formed of, for example, Au, or a metal multi-layer film containing Au.

Meanwhile, on the support 30, the electrodes 30a and 30b are formed to contain Au or the like at their surfaces. The support 30 and the laminate 16 on the crystal growth substrate 90 are bonded by wafer bonding using heating, pressing, and the like, such that the electrode 30a and the first electrode 24 are bonded and the electrode 30b and the second electrode 20 are bonded.

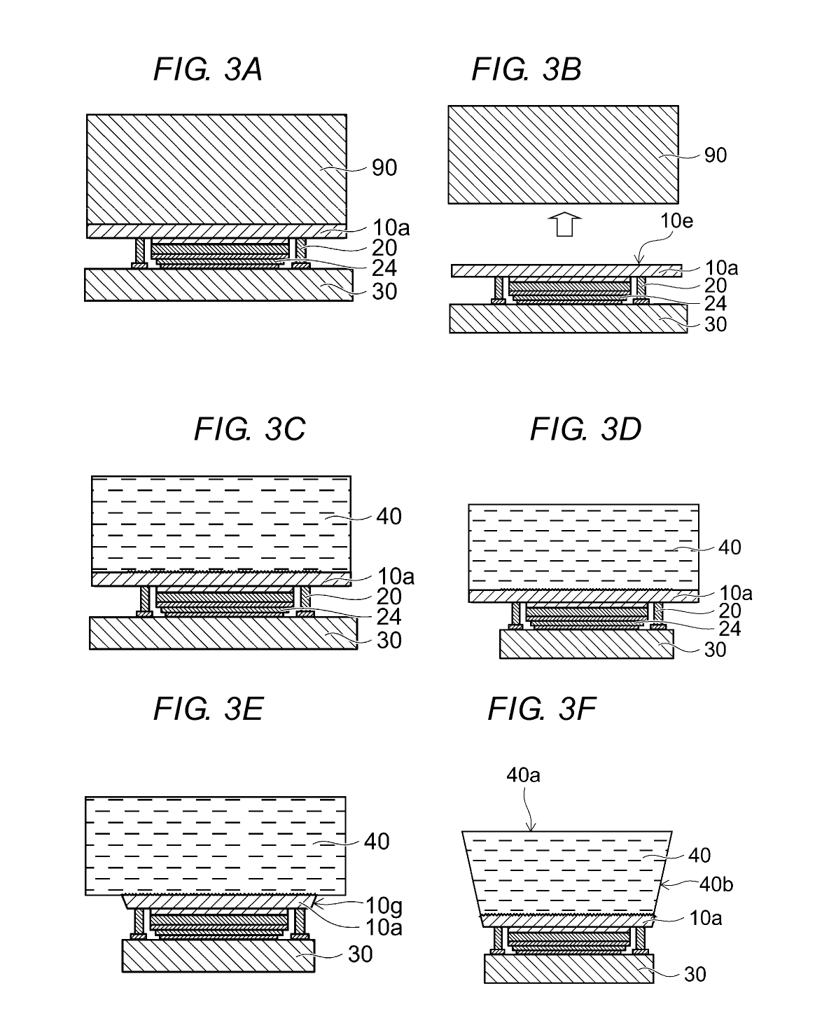

FIGS. 3A to 3F are schematic views illustrating the process of manufacturing the nitride semiconductor light emitting device according to the first embodiment after the wafer bonding.

By wafer bonding, it is possible to obtain a structure shown in FIG. 3A. After bonding, as shown in FIG. 3B, the crystal growth substrate 90 is removed. Next, as shown in FIG. 3C, the second layer 10 is thinned (e.g., by polishing or grinding) to a predetermined thickness, then the phosphor layer 40 is formed on the second layer. The phosphor layer 40 may be formed by mixing Yttrium-Aluminum-Garnet (YAG) phosphor particles or the like in a transparent pre-resin liquid, applying the mixture, and then performing thermal curing or the like to set the resin.

Subsequently, as shown in FIG. 3D, unnecessary layer portions are removed such that the support 30 has a predetermined size.

Subsequently, as shown in FIG. 3E, the cladding layer 10a of the second layer 10 is removed by etching or the like, such that the cladding layer 10a has a predetermined size and its outer edge surface has a predetermined inclination angle. As shown in FIG. 3F, division of the light emitting elements is performed by etching or dicing in a manner such that the resulting outer edge surface of the phosphor layer 40 has a predetermined inclination angle. This division process is not limited to etching or dicing methods and the outer surface of phosphor layer 40 may be formed in the predetermined inclination angle in a separate step from a primary etching/dicing step.

The planar shape of the nitride semiconductor light emitting device may be set to have a 0.5 mm first side length L1 and a second side length L2 equal to L1. L1 and L2 need not be equal and the planar shape of the light emitting may have a rectangular or other shape.

Optionally the second layer 10 may be etched up to the middle thereof (that is, a portion of the second layer from a surface level to an interior level may be removed by etching), and the edge portion side surface of the second layer 10 may be etched such that its side surface (lateral surface) is inclined, and the support 30 may be partially removed, and the division may be performed by etching and dicing such that the side surface of the phosphor layer 40 is inclined.

The operational effects of the first embodiment will be described. The first electrode 24 being formed to widely cover the surface of the light emitting layer 12 and provides a relatively short travel distance for charge carriers to the light emitting layer 12, and thus is likely to widely spread carriers into a luminous area ER of the light emitting layer 12. For this reason, it is possible to lower the probability of Auger non-emitting (non-radiative) recombination and carrier overflow, and to thereby improve luminous efficiency. Auger recombination dissipates energy generated by recombination to other carriers rather than emitting photons, thereby causing non-emitting recombination, resulting in a reduction in the luminous efficiency. The probability of Auger recombination increases as an electron concentration or a hole concentration increases. As a result, a reduction in the luminous efficiency in a high-current operation is suppressed, and it is possible to further improve the optical output.

When the second electrode 20 is set as the n-side electrode, it is possible to spread electrons, which have mobility higher than that of holes, into the luminous area ER of the light emitting layer 12. But since the first electrode (the p-side electrode) is provided to widely cover the surface of the light emitting layer 12 and has a relatively short travel distance to the light emitting layer 12, the first electrode 24 is likely to spread holes, which having mobility lower than that of electrons, into the luminous area ER of the light emitting layer 12. Therefore, it is possible to further improve the luminous efficiency. As a result, it is possible to further improve the optical output in a high-current operation.

In the first embodiment, at the outer surface 10g of the laminate 16 and the outer surface 40b of the phosphor layer 40, it is possible to reflect emitted light g1, which is initially directed outward, inward toward the central axis of the light emitting device. Thus, in the vicinity the central axis of the nitride semiconductor light emitting device, the light intensity (luminous intensity) of wavelength converted light and emitted light from the light emitting layer 12 is improved, and the percentage of emitted light passing through the outer peripheral portion of the phosphor layer 40 decreases. As a result, color irregularity of mixed light at the outer peripheral portion of the nitride semiconductor light emitting device improves (decreases).

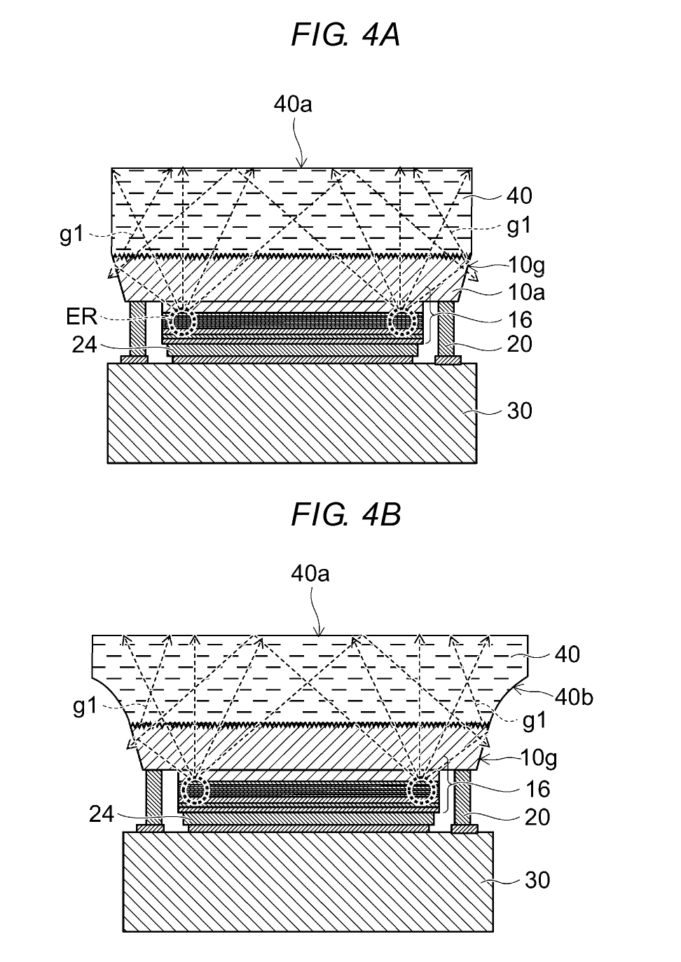

FIG. 4A is a schematic cross-sectional view illustrating a nitride semiconductor light emitting device according to a first modification of the first embodiment, and FIG. 4B is a schematic cross-sectional view illustrating a nitride semiconductor light emitting device according to a second modification of the first embodiment.

As shown in FIG. 4A, the side surface of the phosphor layer 40 need not be inclined, and only the side surface of the laminate 16 is inclined. Alternatively, as shown in FIG. 4B, an inclined surface can be formed up to the middle of the side surface and then cutting may be performed by dicing or the like, whereby device division may be performed. The inclined surface thus formed may be a curved surface, as depicted in FIG. 4B.

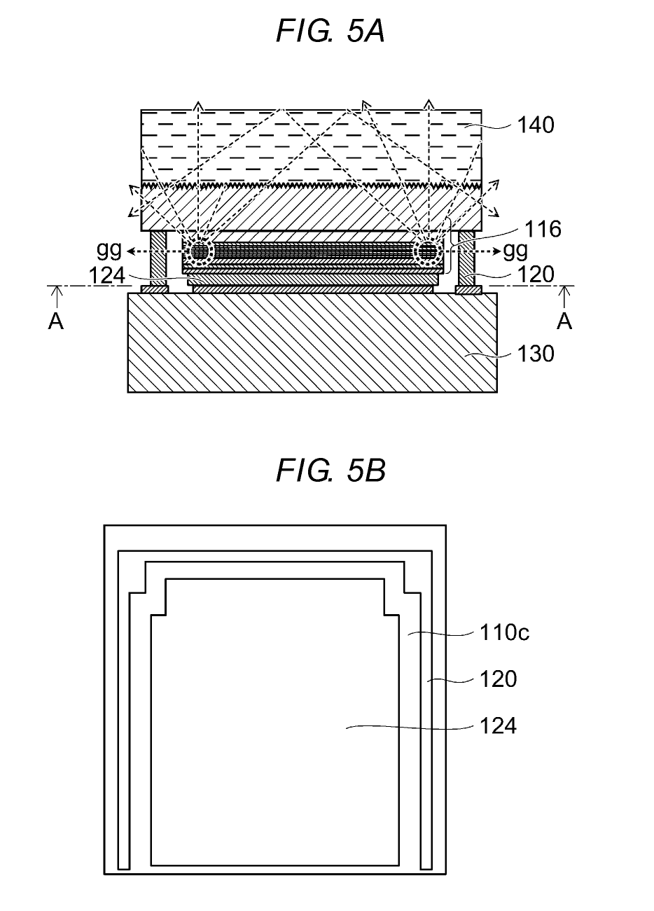

FIG. 5A is a schematic cross-sectional view illustrating a nitride semiconductor light emitting device according to a first comparative example, and FIG. 5B is a schematic plan view illustrating the laminate side as seen along a line A-A of FIG. 5A.

In the nitride semiconductor light emitting device according to the first comparative example, the side surface of a phosphor layer 140 and the side surface of a laminate 116 are perpendicular to the surface of a support 130. A large proportion of light gg emitted laterally (left-right page direction) from the a light emitting layer 112 is emitted from the side surface of the edge portion side surface or the side surface of a step portion 116m to the outside. For this reason, it is difficult to improve optical output. As depicted in FIG. 5B, the surface 110c of laminate 116 has a projected planar area equal to a projected planar area of the interface between phosphor layer 140 and laminate 116.

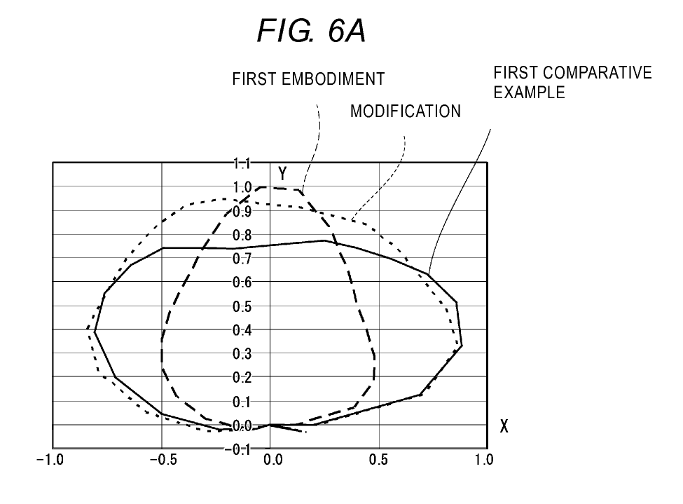

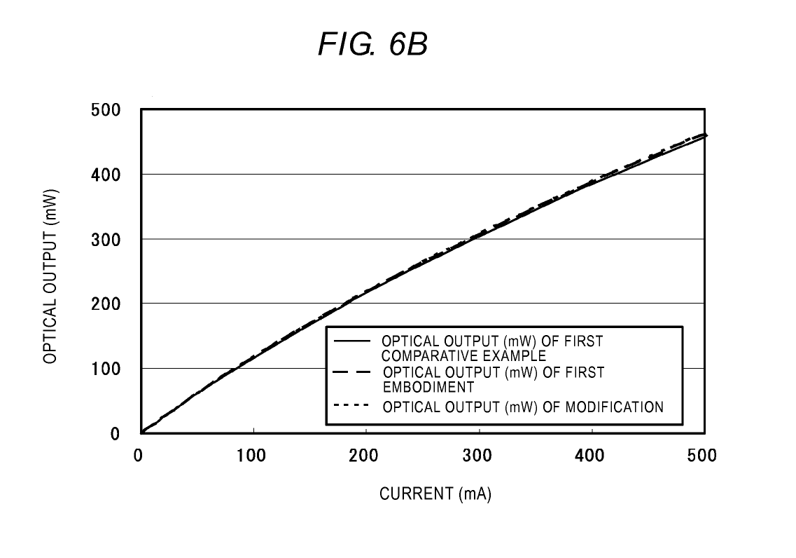

FIG. 6A is a graph illustrating light distribution characteristics obtained by simulation, and FIG. 6B is a graph illustrating dependence of optical output on operating current obtained by simulation. In FIG. 6A, the X-axis corresponds to the relative horizontal position (left-right page direction) in the cross-sectional views, such as in FIG. 1A, FIG. 4A, FIG. 4B, and FIG. 5A. The Y-axis in FIG. 6A corresponds to the relative vertical position in the cross-sectional views.

As simulated, the first embodiment has improved (greater) luminous intensity in vicinity of central area of the phosphor layer 40 when compared to the first comparative example. Therefore, it is possible to reduce color irregularity at the outer peripheral portion of the phosphor layer 40. The axial luminous intensity of the modification of the first embodiment is between the first embodiment and the first comparative example. Further, as shown in FIG. 6B, it is possible to make the overall optical output intensity of the first embodiment and a modification of the first embodiment equal to or greater than that of the first comparative example. Therefore, it is possible to make device brightness increase even as the axial luminous intensity increases.

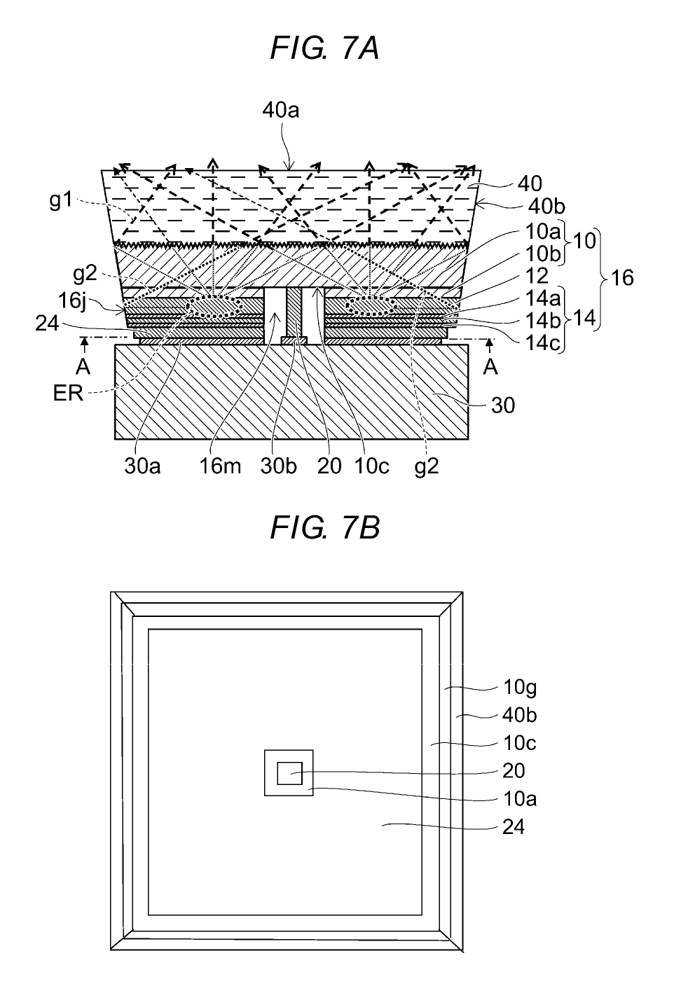

FIG. 7A is a schematic cross-sectional view illustrating a nitride semiconductor light emitting device according to a second embodiment, and FIG. 7B is a schematic plan view illustrating the laminate side as seen along a line A-A of FIG. 7A. As depicted in FIG. 7B, the second electrode 20 contacts base surface 10c of the second layer 10 at central portion of the second layer such that the second electrode is between outer edges of the laminate 16.

The laminate 16 has a step portion (recess) 16m formed from the surface of the first layer 14 up to a portion of the second layer 10 at the central portion of base surface 10c. As depicted, a portion 10b of second layer 10 may be at a level below base surface 10c. The outer surface 16j of the laminate 16 is inclined such that the cross section of the laminate 16 widens toward the light emitting surface 40a of the phosphor layer 40 as shown in FIG. 7A. In this case, a portion g2 of emitted light from the light emitting layer 12 toward the outer surface 16j is reflected by the inclined outer surface 16j. Therefore, it is possible to improve light-extraction efficiency at the light emitting surface 40a in an upward direction. In this example, the cross-section of the phosphor layer 40 also widens toward the light emitting surface 40a.

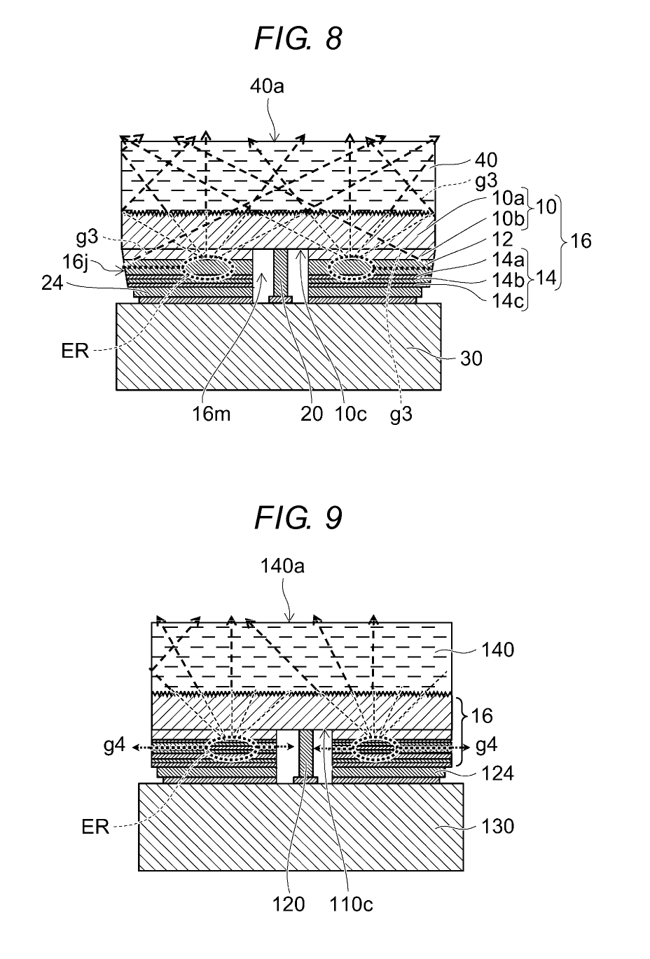

FIG. 8 is a schematic cross-sectional view illustrating a nitride semiconductor light emitting device according to a modification of the second embodiment.

In this modification of the second embodiment, only the outer surface 16j of the laminate 16 is inclined and the cross-section of the phosphor layer 40 does not widen with distance from the interface between laminate 16 and phosphor layer 40. Even in this modification of the second embodiment, it is possible to emit a portion of light reflected from the outer surface 16j upward from the light emitting surface 40a.

FIG. 9 is a schematic cross-sectional view illustrating a nitride semiconductor light emitting device according to a second comparative example.

The outer edge surfaces of the phosphor layer 140 and the outer edge surfaces of laminated layers, which are on support 130 surrounding a second electrode 120, are substantially perpendicular to an emitting surface 140a, and thus it is difficult to concentrate laterally emitted light (e.g., g4) toward the central axis direction of the phosphor layer 140.

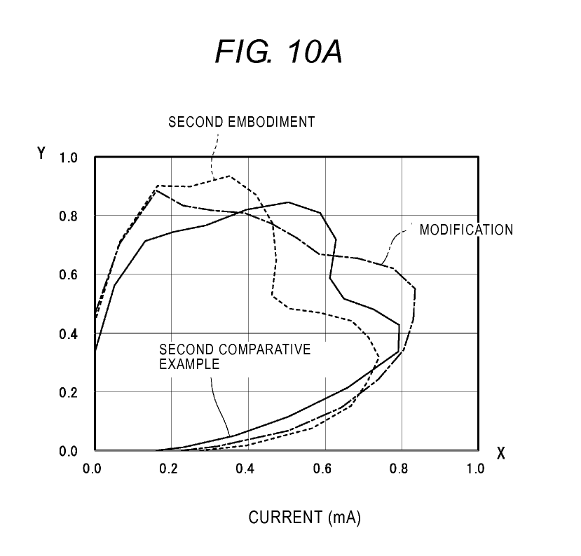

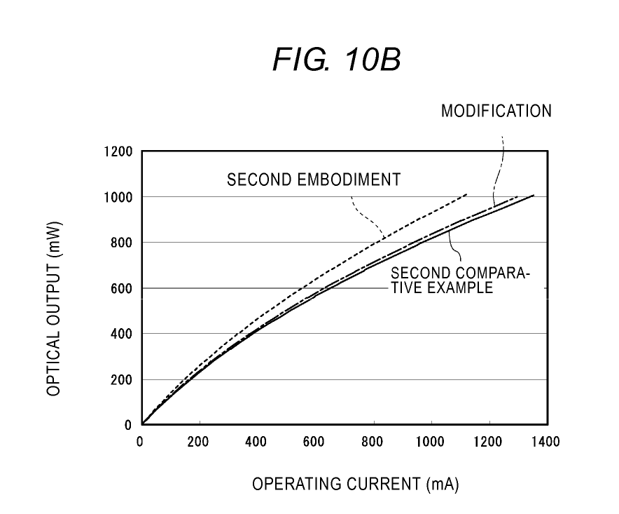

FIG. 10A is a graph illustrating light distribution characteristics obtained by simulations, and FIG. 10B is a graph illustrating dependence of optical output on operating current obtained by simulation.

In FIG. 10A, the horizontal axis X corresponds to the relative horizontal position of the cross-sectional view of FIG. 7A, FIG. 8, or FIG. 9. Further, the vertical axis Y corresponds to the relative vertical position in the cross-sectional view of FIG. 7A, FIG. 8, or FIG. 9.

As shown in FIG. 10A, the luminous intensity in the vicinity of an axial area of a nitride semiconductor light emitting device according to a modification is higher than the luminous intensity in the vicinity of an axial area of the second comparative example. Further, it is possible to make the luminous intensity in the vicinity of an axial area of the second embodiment higher than that of the modification. That is, when an inclined surface is formed, the luminous intensity in the vicinity of an axial area is improved.

As shown in FIG. 10B, when operating current is 1,000 mA, the optical output of the second comparative example is about 810 mW. And when operating current is 1,000 mA, the optical output of the second embodiment is about 930 mW, which is about 15% greater than that of the second comparative example.

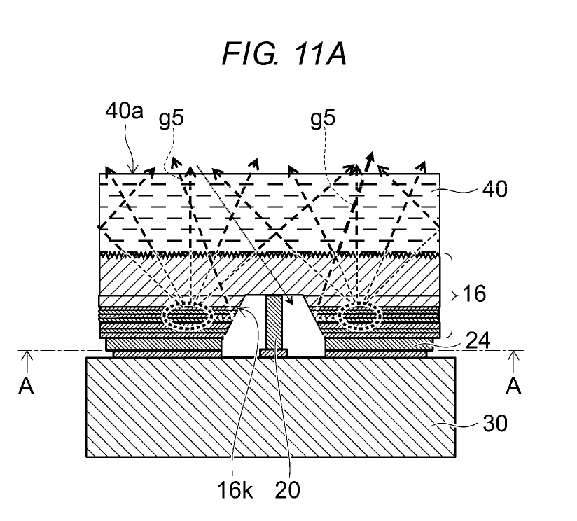

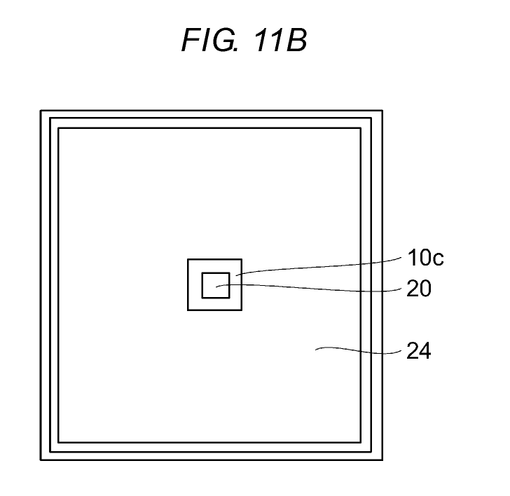

FIG. 11A is a schematic cross-sectional view illustrating a nitride semiconductor light emitting device according to a third embodiment, and FIG. 11B is a schematic plan view illustrating the laminate side as seen along a line A-A of FIG. 11A.

The laminate 16 includes a step portion (recess) 16m at the central portion of the laminate 16—that is, step portion 16m is formed in the center, as viewed from a direction perpendicular to surface 10c, of laminate 16. The inner surface 16k of the step portion 16m is inclined such that the width of the laminate 16 widens toward the phosphor layer 40. Light g5 emitted from the light emitting layer 12 and directed toward the inner surface 16k is reflected by the inner surface 16k upward towards the light emitting surface 40a.

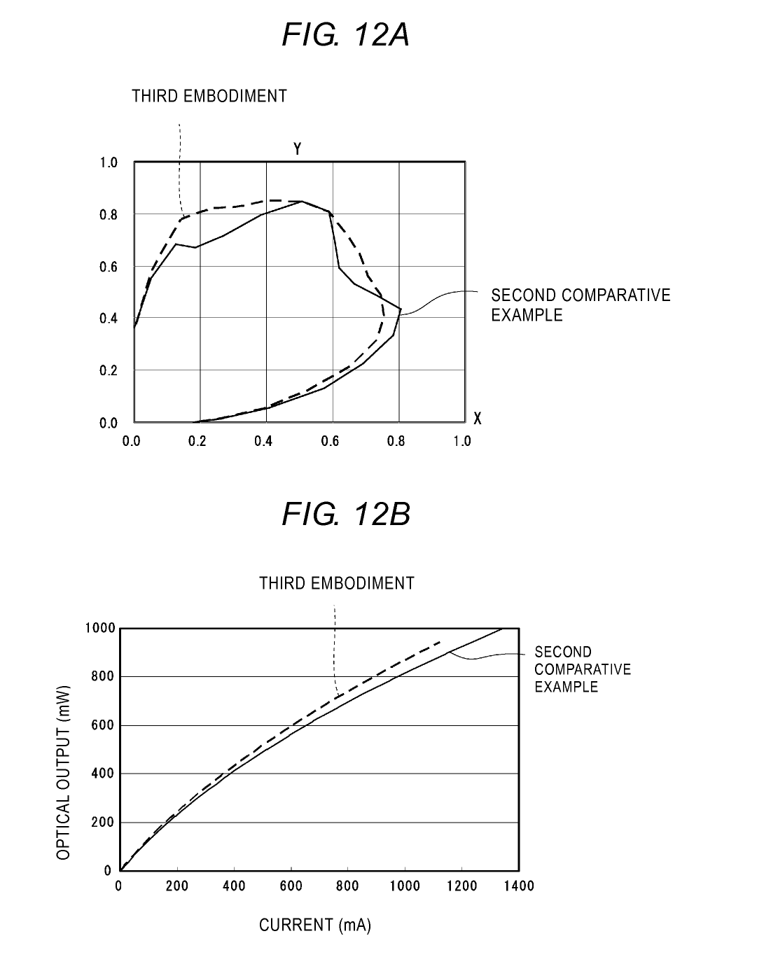

FIG. 12A is a graph illustrating light distribution characteristics obtained by simulation, and FIG. 12B is a graph illustrating dependence of optical output on operating current obtained by simulation.

As shown in FIG. 12A, it is possible to make the luminous intensity in the vicinity of an axial area of the third embodiment higher than the luminous intensity in the vicinity of an axial area of the second comparative example shown in FIG. 9. That is, when an inclined surface is formed on the surface of step portion 16m, the luminous intensity in the vicinity of an axial area of the device can be improved relative to the second comparative shown in FIG. 9. Further, as shown in FIG. 12B, when operating current is 1,000 mA, the optical output of the third embodiment is about 870 mW which is about 9% greater than the optical output of the second comparative example, which is 800 mW.

According to the first to third embodiments, it is possible to provide a nitride semiconductor light emitting device having higher axial luminous intensity and less color irregularity in mixed light emitted from the device. Such nitride semiconductor light emitting devices may be used in a wide variety of applications such as in illuminating devices, displays, signals transmission, and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting device comprising:
a laminate body including a first layer having a first-conductivity type, a first part of a second layer having a second-conductivity type, and a light emitting layer containing a nitride semiconductor between the first layer and the second layer;
a phosphor layer having a light emitting surface;
a second part of the second layer between the phosphor layer and the laminate body;
a first electrode formed on a surface of the first layer; and
a second electrode formed on a surface of the second part of the second layer,
wherein at least one of the laminate body, the second part of the second layer, and the phosphor layer widens toward the light emitting surface.

2. The light emitting device according to claim 1, wherein side surfaces of the phosphor layer and the second part of the second layer are not perpendicular to the light emitting surface.

3. The light emitting device according to claim 2, wherein side surfaces of the laminate body are perpendicular to the light emitting surface.

4. The light emitting device according to claim 3, wherein side surfaces of the phosphor layer each have a concave curvature.

5. The light emitting device according to claim 1, wherein side surfaces of the second part of the second layer are not perpendicular to the light emitting surface, and side surfaces of the phosphor layer and the laminate body are perpendicular to the light emitting surface.

6. The light emitting device according to claim 1, wherein side surfaces of each of the phosphor layer, the second part of the second layer, and the laminate body are not perpendicular to the light emitting surface.

7. The light emitting device according to claim 6, wherein the second electrode extends through a recess formed in an interior region of the laminate body to contact a central portion of the surface of the second part of the second layer.

8. A light emitting device comprising:
a laminate body including a first layer having a first-conductivity type, a first part of a second layer having a second-conductivity type, and a light emitting layer containing a nitride semiconductor between the first layer and the second layer;
a phosphor layer having a light emitting surface;
a second part of the second layer between the phosphor layer and the laminate body;
a first electrode formed on a surface of the first layer; and
a second electrode formed on a surface of the second part of the second layer and extending through a recess formed in an interior region of the laminate body to contact a central portion of the surface of the second part of the second layer and divide the laminate body into first and second parts,
wherein the first and second parts of the laminate body each widen toward the light emitting surface.

9. The light emitting device according to claim 8, wherein outer side surfaces of the laminate body are not perpendicular to the light emitting surface and inner side surfaces of the laminate body are perpendicular to the light emitting surface.

10. The light emitting device according to claim 9, wherein side surfaces of the phosphor layer and the second part of the second layer are not perpendicular to the light emitting surface.

11. The light emitting device according to claim 8, wherein inner side surfaces of the laminate body are not perpendicular to the light emitting surface and outer side surfaces of the laminate body are perpendicular to the light emitting surface.

12. The light emitting device according to claim 11, wherein side surfaces of the phosphor layer and the second part of the second layer are perpendicular to the light emitting surface.

13. A light emitting device comprising:
a laminate body having a base portion and a protruding portion that includes:
a first layer having a first-conductivity type,
a second layer having a second-conductivity type, and
a light emitting containing a nitride semiconductor between the first layer and the second layer;
a first electrode formed on a surface of the first layer;
a second electrode formed on a surface of the base portion; and
a phosphor layer that is formed on a surface of the second layer placed on a side opposite to the light emitting layer, and has a light emitting surface,
wherein side surfaces of one of the phosphor layer, the base portion, and the protruding portion are not perpendicular to the light emitting surface and widen relative to each other toward the light emitting surface.

14. The light emitting device according to claim 13, wherein the side surfaces of the phosphor layer and the base portion widen relative to each other toward the light emitting surface and the side surfaces of the protruding portion are perpendicular to the light emitting surface.

15. The light emitting device according to claim 14, wherein side surfaces of the phosphor layer each have a concave curvature.

16. The light emitting device according to claim 13, wherein the side surfaces of the base portion widen relative to each other toward the light emitting surface and the side surfaces of the phosphor layer and the protruding portion are perpendicular to the light emitting surface.

17. The light emitting device according to claim 13, wherein the second electrode extends through a recess formed in an interior region of the laminate body to contact a central portion of the surface of the base portion.

18. The light emitting device according to claim 17, wherein the side surfaces of each of the phosphor layer and the base portion are not perpendicular to the light emitting surface, and outer side surfaces of the protruding portion are not perpendicular to the light emitting surface.

19. The light emitting device according to claim 17, wherein the recess divides the protruding portion into a first part and a second part, each of the first part and the second part having side surfaces that widen relative to each other toward the light emitting surface.

20. The light emitting device according to claim 19, wherein one of the side surfaces of the first and second parts is perpendicular to the light emitting surface and the other of the side surfaces of the first and second parts is not perpendicular to the light emitting surface.
